(19) United States
(12) Patent Application Publication
(10) Pub. No.: US 2009/0163010 A1
(43) Pub. Date: Jun. 25, 2009

(54) METHOD FOR FABRICATING SEMICONDUCTOR DEVICE

(75) Inventors: Sang-Rok OH, Ichon-shi (KR); Hyun-Sik PARK, Ichon-shi (KR); Yong- Tae CHO, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-Shi (KR)

(21) Appl. No.: 12/336,850

(22) Filed: Dec. 17, 2008

(30) Foreign Application Priority Data
Dec. 21, 2007 (KR) 10-2007-0135301

(51) Int. Cl. H01L 21/3213; H01L 21/311; H01L 21/467

(52) U.S. Cl. 438/587; 438/700; 257/E21.305; 257/E21.486

(57) ABSTRACT

A method for fabricating a semiconductor device includes forming a plurality of gate patterns including a tungsten electrode over a substrate, performing a plasma oxidation process to form a capping layer on the surfaces of the gate patterns, forming an etch barrier layer over the substrate where the capping layer is formed, forming an interlayer dielectric layer to fill gap between the gate patterns, and etching the interlayer dielectric layer between the gate patterns to form a contact hole.

### CROSS-REFERENCE TO RELATED APPLICATIONS

The present invention claims priority of Korean patent application number 10-2007-0135301, filed on Dec. 21, 2007, which is incorporated by reference in its entirety.

### BACKGROUND OF THE INVENTION

The present invention relates to a method for fabricating a semiconductor device, and more particularly, to a method for fabricating a semiconductor device, which is capable of preventing failure in a gate pattern using a tungsten layer.

Recently, gate conductive layers for a semiconductor device are being implemented in a stacked structure with a polysilicon layer and tungsten layer instead of a single-layered structure with just a single polysilicon layer. This is done to reduce the resistance of the gate conductive layer. However, although the stacked structure of the tungsten layer and the polysilicon layer can reduce the resistance of the gate conductive layer, an abnormal oxidation may occur in the tungsten layer during a thermal treatment subsequent to a gate patterning process.

FIGS. 1A and 1B are micrographic views of the abnormal oxidation of the tungsten layer. Due to the abnormal oxidation of the tungsten layer 11, the tungsten layer 11 becomes deformed and may finally break away. A reference numeral 12 shows that the tungsten layer 11 is broken away and exposed to the outside. To overcome such a limitation, an advanced sidewall (ASW) gate has been proposed.

FIG. 2 illustrates a cross-sectional view of an advanced sidewall (ASW) gate. In FIG. 2, the ASW gate includes a gate pattern having a gate dielectric 22, a polysilicon electrode 23, a tungsten electrode 24, and a gate hard mask layer 25, which are stacked over a substrate 21. A capping layer 26, a passivation layer 27, gate spacers 28, and an etch barrier layer 29 are formed on sidewalls of the gate pattern. The etch barrier layer 29 protects the gate pattern and the substrate 21 in an SAC etching process.

The capping layer 26 is a thin film for preventing the abnormal oxidation of a tungsten layer, and the passivation layer 27 is a thin film for preventing gate induced drain leakage (GIDL) and hot electrons, which are caused by smooth edges of the gate pattern. Furthermore, the capping layer 26, the passivation layer 27, the gate spacers 28, and the etch barrier layer 29 are thin films for protecting the gate pattern from an external environment, for example, an etching process.

The ASW gate can prevent the abnormal oxidation of the tungsten layer in the above manner, but it has the following limitations. First, as indicated by a reference numeral 31 in the micrographic view of FIG. 3A, the gate pattern can lean to one side because of thermal stress, for example when a deposition temperature of 700° C. or higher is applied to the gate pattern in deposition of the capping layer 26.

Second, as can be seen from the micrographic view of FIG. 3B, a monitored critical dimension (CD) of the tungsten electrode 24 is “CD2”, but its actual CD (minus the capping layer 26) is “CD1”. That is, an area of the ASW gate is smaller than that of a typical gate in which the capping layer 26 is not formed. This reduces a contact area of the tungsten electrode 24 with the polysilicon layer 23. Hence, the sheet resistance of the gate pattern increases, thus causing an easy failure.

Third, as can be seen from the micrographic view of FIG. 3C, the gap between the gate patterns is reduced by a triple-layered structure having the capping layer 26, the gate spacers 28, and the etch barrier layer 29 for protecting the gate pattern, thus increasing an aspect ratio. Consequently, the substrate may not be exposed in an etching process for forming a landing plug, and the thin films for protecting the gate pattern may be excessively lost.

Therefore, there is a need for techniques that can prevent the leaning of the gate patterns, prevent the increase in the sheet resistance of the gate pattern, and prevent the reduction in the gap between the gate patterns.

### SUMMARY OF THE INVENTION

Embodiments of the present invention are related to a method for fabricating a semiconductor device, which is capable of preventing the abnormal oxidation of a tungsten electrode and the leaning of a gate pattern.

Also, embodiments of the present invention are directed to providing a method for fabricating a semiconductor device, which is capable of simplifying a fabrication process by reducing number of processes for forming a thin film for protecting a gate pattern, and securing a space for a contact hole.

Furthermore, embodiments of the present invention are directed to providing a method for fabricating a semiconductor device, which is capable of securing a sufficient CD of a tungsten electrode, thereby reducing the sheet resistance of a gate pattern.

In accordance with an aspect of the present invention, there is provided a method for fabricating a semiconductor device. The method includes forming a plurality of gate patterns including a tungsten electrode over a substrate, performing a plasma oxidation process to form a capping layer on the surfaces of the gate patterns, forming an etch barrier layer over the substrate where the capping layer is formed, forming an interlayer dielectric layer to fill gap between the gate patterns, and etching the interlayer dielectric layer between the gate patterns to form a contact hole.

### BRIEF DESCRIPTION OF THE DRAWINGS

FIGS. 1A and 1B are micrographic views of the abnormal oxidation of a tungsten layer.

FIG. 2 illustrates a cross-sectional view of an advanced sidewall (ASW) gate.

FIG. 3A illustrates a micrographic view of a leaned gate pattern.

FIG. 3B illustrates a micrographic view of a width of a capping layer.

FIG. 3C illustrates a micrographic view of a triple-layered thin film for protecting a gate pattern.

FIGS. 4A to 4H illustrate a method for fabricating a semiconductor device in accordance with an embodiment of the present invention.

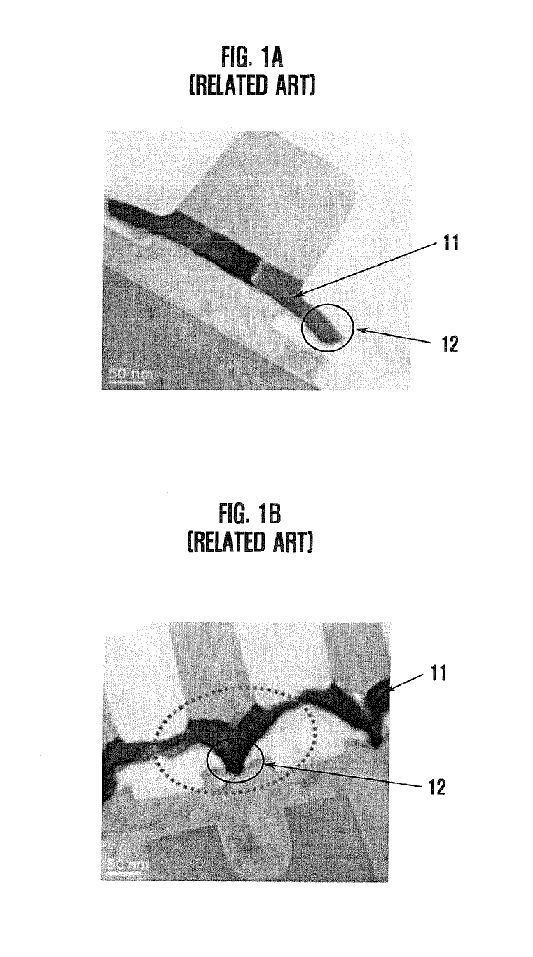

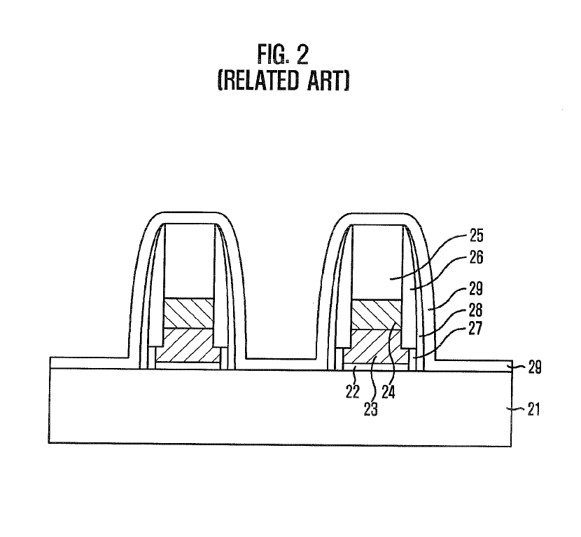

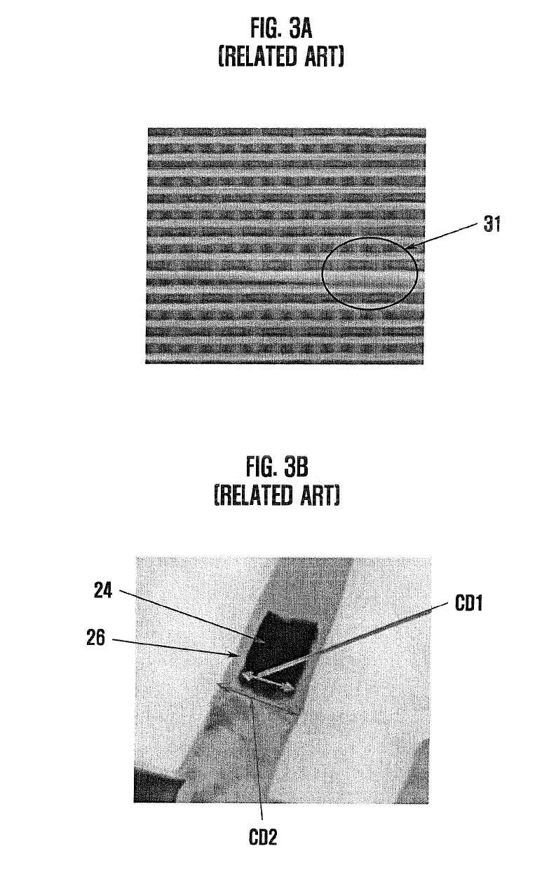

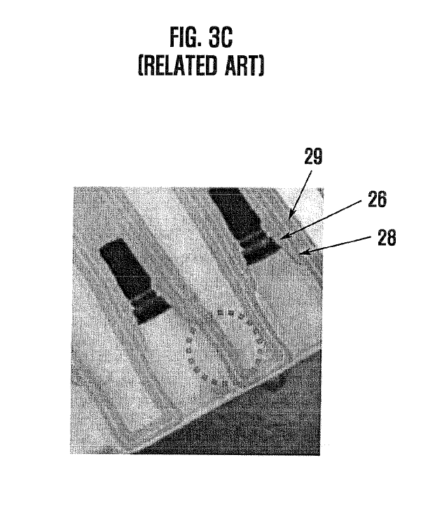

### DESCRIPTION OF SPECIFIC EMBODIMENTS

Hereinafter, a method for fabricating a semiconductor device in accordance with the present invention will be described in detail with reference to the accompanying drawings.

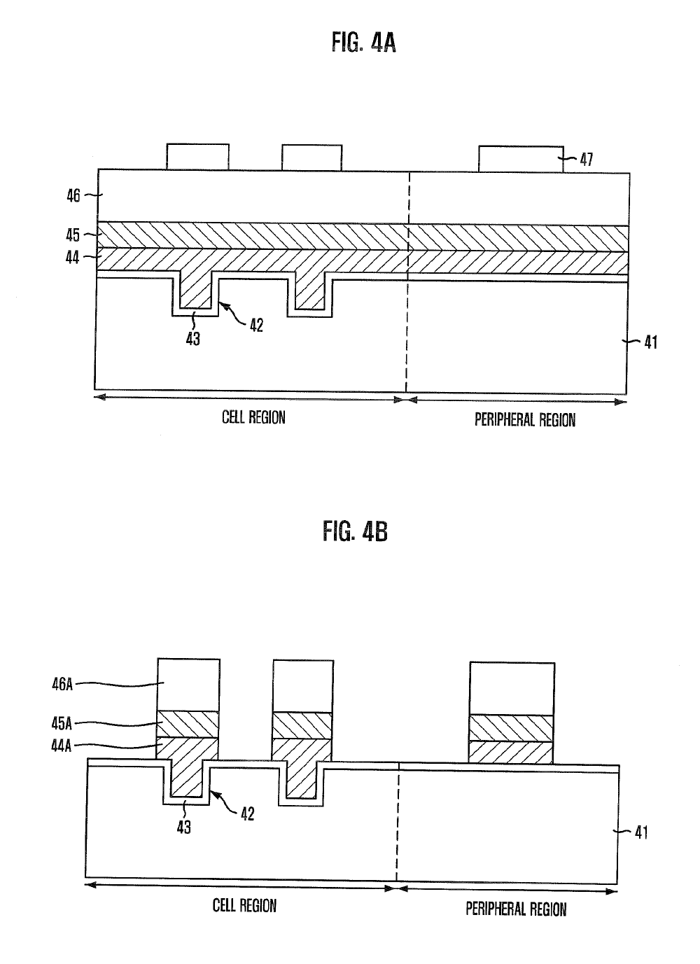

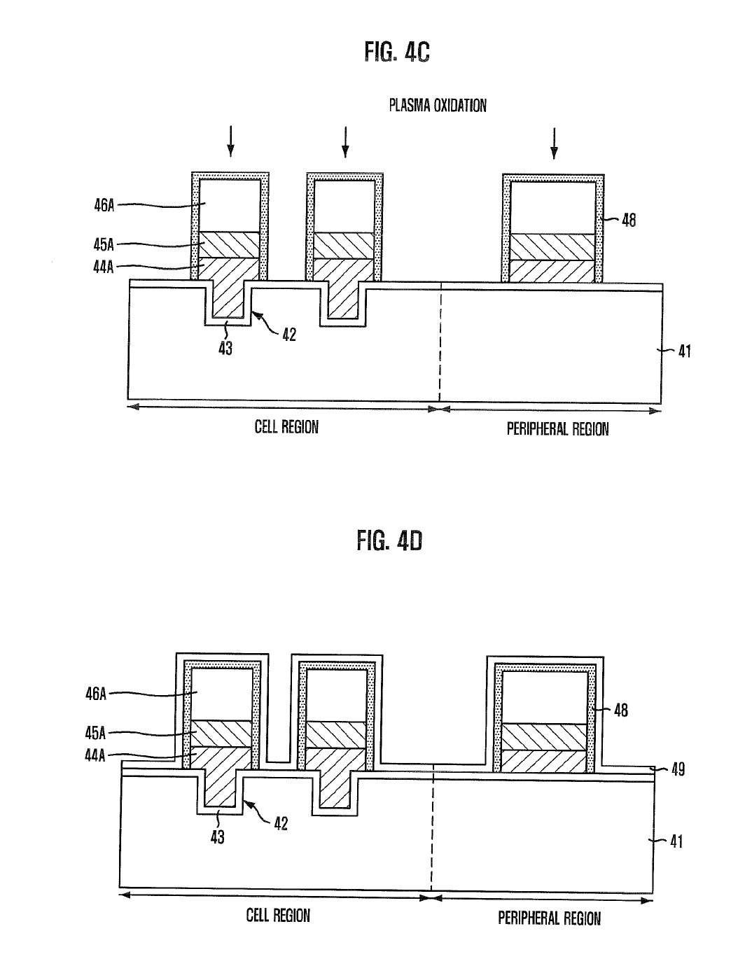

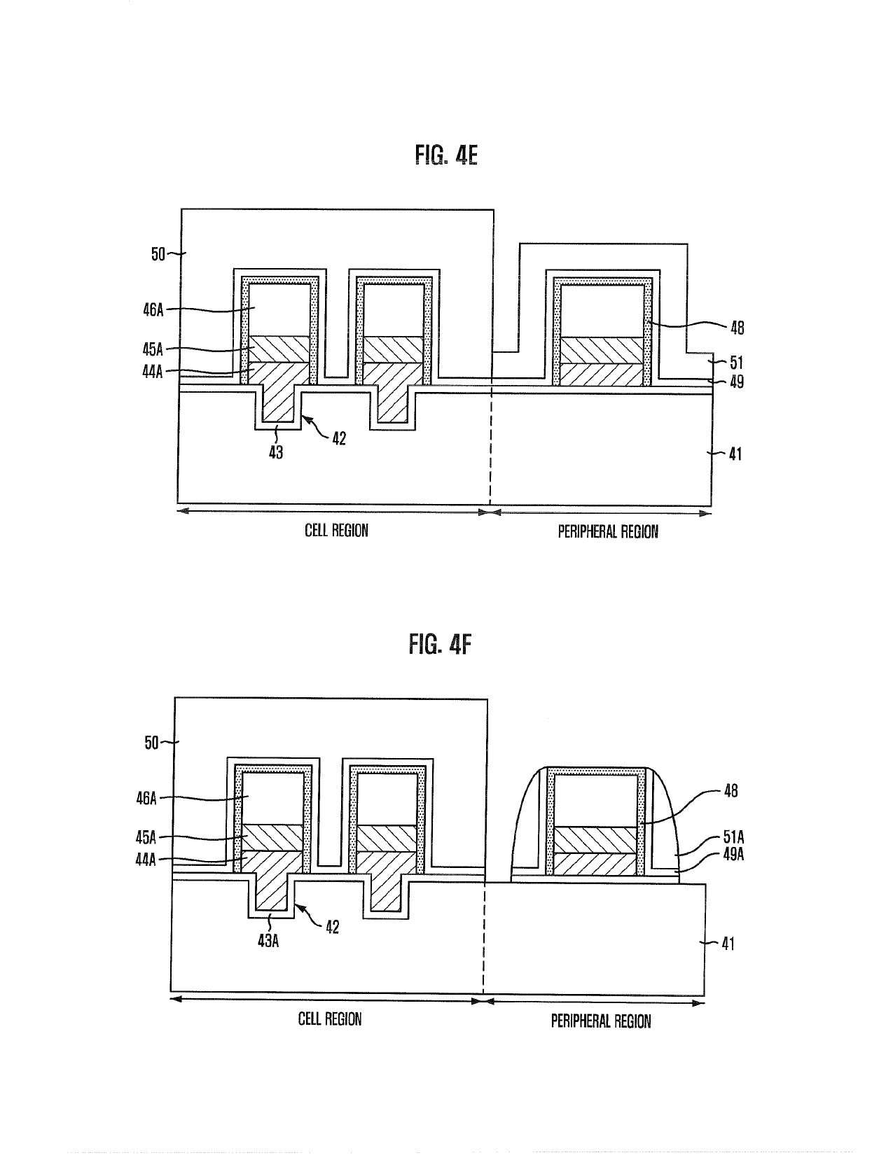

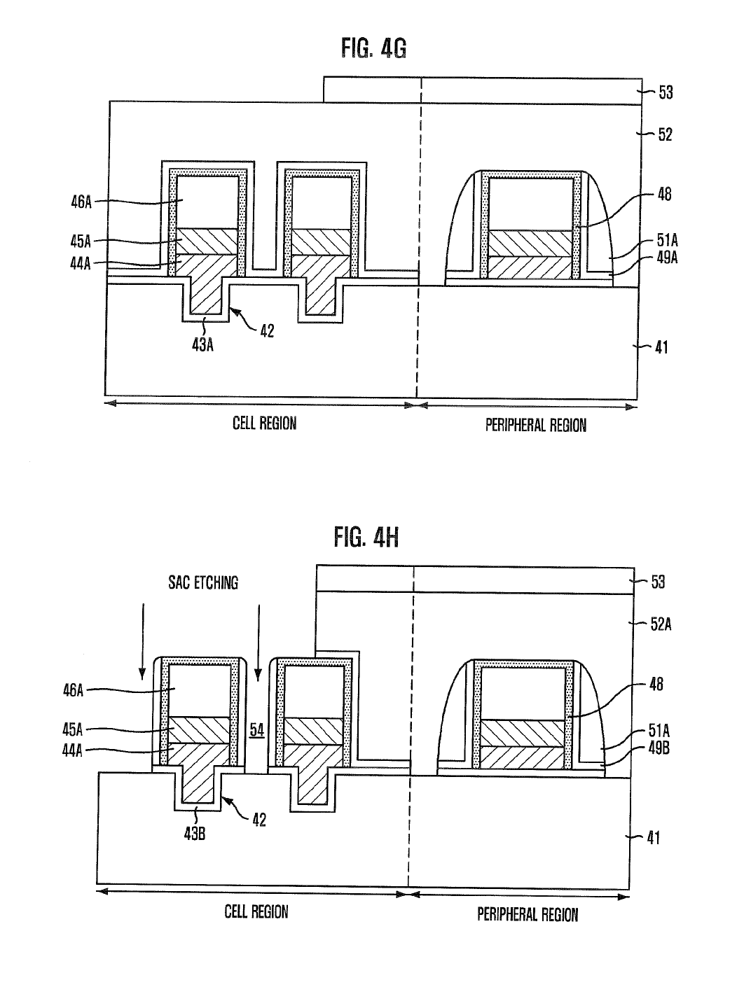

FIGS. 4A to 4H illustrate a method for fabricating a semiconductor device in accordance with an embodiment of the present invention. In FIG. 4A, a cell region and a peripheral region are defined in a substrate 41, and a recess pattern 42 is formed in the cell region of the substrate 41. A gate dielectric 43 is formed along the surface of the recess pattern 42 and the surface of the substrate 41.

The cell region corresponds to a region of a unit memory cell group, and the peripheral region corresponds to a region of an element group for controlling the operation of unit memory cells and the data transfer operation.

The recess pattern 42 may be formed in a polygonal shape, a bulb shape, or a saddle shape. The bulb-shaped recess pattern has a rounded lower portion so that its lower portion is wider than its upper portion. The saddle-shaped recess pattern has a fin on the bottom surface.

The gate dielectric 43 includes an oxide layer, for example, a silicon oxide (SiO₂) layer formed by an oxidation process. A polysilicon layer 44 is formed to fill the recess pattern 42. A tungsten layer 45 and a gate hard mask layer 46 are sequentially formed over the polysilicon layer 44. The gate hard mask layer 46 includes a nitride layer, for example, a silicon nitride (Si₃N₄) layer.

A diffusion barrier layer including a tungsten nitride (WN) layer and a tungsten silicide (WSi) layer may be further formed between the polysilicon layer 44 and the tungsten layer 45. In addition, a polysilicon layer serving as an etch stop layer in etching the gate hard mask layer 46 may be further formed between the tungsten layer 45 and the gate hard mask layer 46.

A photoresist pattern 47 is formed over the gate hard mask layer 46. A hard mask layer may be further formed between the photoresist pattern 47 and the gate hard mask layer 46 in the case that the gate hard mask layer 46 may not be sufficiently etched using the photoresist pattern 47 alone. The hard mask layer may include an amorphous carbon layer.

Referring to FIG. 4B, gate patterns are formed in the cell region and the peripheral region by sequentially etching the gate hard mask layer 46, the tungsten layer 45, and the polysilicon layer 44 using the photoresist pattern 47 as an etch barrier. In addition, the gate patterns may be formed by etching down to the gate dielectric 43.

The etching of the gate hard mask layer 46, the tungsten layer 45, and the polysilicon layer 44 is performed using a mixed gas of CF₄ and CHF₃ and inductively coupled plasma (ICP), capacitively coupled plasma, or electron-cyclotron resonance type plasma source.

The photoresist pattern 47 is removed. Reference numerals 44A, 45A and 46A represent, respectively, a polysilicon electrode, a tungsten electrode, and a gate hard mask pattern, which are formed after the etching for forming the gate patterns.

Referring to FIG. 4C, a capping layer 48 is formed by oxidizing the resulting structure where the gate patterns are formed. The capping layer 48 is formed by a low-temperature plasma oxidation process. The capping layer 48 prevents the abnormal oxidation of the tungsten electrode 45A and protects the gate patterns.

The plasma oxidation process uses only a mixed gas of CF₄, O₂ and N₂. It also uses an RF power and a source power for ionizing the mixed gas into a plasma state at a chamber temperature of approximately 300° C. to approximately 600° C. In one embodiment, the chamber temperature is kept at no more than 400° C. In another embodiment, the chamber temperature is kept at no more than 500° C. In addition, the plasma oxidation process is performed in-situ within a chamber where the process for forming the gate patterns is carried out. A flow rate of the CF₄ gas ranges from approximately 40 sccm to approximately 60 sccm, a flow rate of the O₂ gas ranges from approximately 20 sccm to approximately 30 sccm, and a flow rate of the N₂ gas ranges from approximately 100 sccm to approximately 990 sccm.

Since the plasma oxidation process uses only O₂ radical, oxidation penetration into the tungsten electrode 45 can be minimized, thereby preventing the abnormal oxidation of the tungsten electrode 45. Hence, a high-temperature deposition of the capping layer can be omitted, thereby preventing the leaning of the gate patterns.

The capping layer 48 may be formed to a thickness of approximately 50 Å to approximately 300 Å. In one embodiment, the capping layer 48 may be formed to a thickness of approximately 60 Å to approximately 100 Å. In addition, a cleaning process using ozone (O₃) may be performed for adjusting the thickness of the capping layer 48.

An ion implantation process is performed to form source and drain regions in the cell region and the peripheral region. The source and drain region of the cell region may be formed by performing a diffusion process on a landing plug. That is, the source and drain region is formed by diffusing impurities doped in the landing plug toward the substrate 41.

Referring to FIG. 4D, an etch barrier layer 49 is formed over the substrate 41 where the capping layer 48 is formed. The etch barrier layer 49 is a thin film for protecting the gate patterns in an etching process such as a self aligned contact (SAC) etching process. The etch barrier layer 49 may include a nitride layer. The etch barrier layer 49 may be formed to a thickness of approximately 50 Å approximately 150 Å. In one embodiment, the etch barrier layer 49 may be formed to a thickness of approximately 70 Å to approximately 90 Å.

Referring to FIG. 4E, an etch stop layer 50 covering the gate pattern of the cell region is formed over the etch barrier layer 49 of the cell region. The etch stop layer 50 is formed only in the cell region and protects the gate pattern of the cell region in the etching process and the deposition process performed only on the peripheral region.

A spacer insulation layer 51 is formed over the etch barrier layer 49 of the peripheral region. The spacer insulation layer 51 is left on sidewalls of the gate pattern of the peripheral region by a subsequent process. Thus, the spacer insulation layer 51 serves to protect the sidewalls of the gate pattern. The spacer insulation layer 51 may include a tetra ethyl ortho silicate (TEOS) layer.

Referring to FIG. 4F, the spacer insulation layer 51 is etched by an anisotropic etching process. The gate dielectric 43 and etch barrier layer 49 are also etched. In this way, a gate dielectric pattern 43A, a triple-layered spacer including an etch barrier pattern 49A, and a spacer pattern 51A is formed on the sidewalls of the gate pattern of the peripheral region.

A lightly doped drain (LDD) region is formed by doping low-concentration impurities into the peripheral region.

Referring to FIG. 4G, an interlayer dielectric layer 52 is formed over the resulting structure. A mask pattern 53 is formed which blocks the peripheral region and opens a landing plug region of the cell region. The mask pattern 53 is also called a SAC mask pattern.

Referring to FIG. 4H, the interlayer dielectric layer 52 is etched using the mask pattern 53 as an etch barrier, thereby forming an etched interlayer dielectric layer 52A. Such an etching is called as an SAC etching.

The SAC etching is an etching process using an etch selectivity of an oxide layer to a nitride layer. The oxide layer and the nitride layer correspond to the interlayer dielectric layer 52 and the etch barrier pattern 49A, respectively.

The exposed etch barrier pattern 49A and the gate dielectric pattern 43A are etched to form a contact hole 54 exposing the substrate 41. Reference numerals 43B and 49B represent an etched gate dielectric pattern and an etched etch barrier pattern, respectively. A conductive layer is formed to fill the contact hole 54 and planarized to form a landing plug.

In the above-described embodiment of the present invention, a dual-layered thin film including the capping layer 48 and the etch barrier pattern 49A is used as a thin film for protecting the gate pattern.

The capping layer 48 prevents the abnormal oxidation of the tungsten electrode 45A because it is formed of a low-temperature plasma oxidation process and uses only O₂ radical. In addition, the capping layer 48 protects the gate pattern and is disposed between the gate pattern and the etch barrier pattern 49A to buffer stress of the etch barrier layer.

The low-temperature plasma oxidation process does not apply stress because it is performed at a chamber temperature of approximately 300° C. to approximately 600° C. Therefore, the leaning of the gate pattern can be prevented.

Furthermore, since the dual-layered thin film is used for protecting the gate pattern, the fabrication process can be further simplified compared with the related art using the triple-layered thin film, and the gap between the gate patterns can also be further increased. Therefore, a space for the contact hole can be sufficiently secured.

Moreover, the tungsten electrode 45A and the polysilicon electrode 44A can be formed with the same width. In particular, the width of the tungsten electrode 45A can be increased compared with the related art, the contact area between the tungsten electrode 45A and the polysilicon electrode 44A is increased, thereby reducing the sheet resistance of the gate pattern.

In accordance with the embodiments of the present invention, the gate patterns including the tungsten electrode is protected through the low-temperature plasma oxidation process, thereby preventing the abnormal oxidation of the tungsten electrode. The high-temperature deposition of the capping layer can be omitted and thus the leaning of the gate patterns can be prevented.

Furthermore, the fabrication process can be simplified by reducing number of processes for forming the thin film for protecting the gate pattern. The sheet resistance of the gate pattern can be reduced by securing the sufficient CD of the tungsten electrode. The high-temperature oxidation process for forming the passivation layer (see 27 in FIG. 2) can be omitted.

Therefore, the stability and reliability of the semiconductor device can be improved and the yield of the semiconductor device can also be increased.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A method for fabricating a semiconductor device, the method comprising:
forming a plurality of gate patterns over a substrate, each gate pattern including a tungsten electrode;
forming a capping layer on the surfaces of the gate patterns by performing a plasma oxidation process;
forming an etch barrier layer over the capping layer;
forming an interlayer dielectric layer to fill gap between the gate patterns; and
etching the interlayer dielectric layer between the gate patterns to form a contact hole.

2. The method of claim 1, further comprising, after forming the capping layer, performing a cleaning process using ozone (O₃).

3. The method of claim 1, wherein the plasma oxidation process is performed at a chamber temperature of approximately 30020 C. to approximately 600° C.

4. The method of claim 1, wherein the plasma oxidation process is performed using a mixed gas including CF₄ gas, O₂ gas, and N₂ gas.

5. The method of claim 4, wherein a flow rate of the CF₄ gas ranges from approximately 40 sccm to approximately 60 sccm, a flow rate of the O₂ gas ranges from approximately 20 sccm to approximately 30 sccm, and a flow rate of the N₂ gas ranges from approximately 100 sccm to approximately 990 sccm.

6. The method of claim 1, wherein the capping layer is formed to a thickness of approximately 50 Å to approximately 300 Å.

7. The method of claim 1, wherein the capping layer is formed in-situ in an etching chamber for forming the gate patterns.

8. The method of claim 1, wherein the forming of the gate patterns comprises:
sequentially forming a gate dielectric, a polysilicon electrode, a tungsten electrode, a gate hard mask layer, and a photoresist pattern over the substrate; and
sequentially etching the gate hard mask layer, the tungsten electrode, and the polysilicon electrode using the photoresist pattern as an etch mask.

9. The method of claim 1, wherein the etch barrier layer comprises a nitride layer.

10. The method of claim 1, wherein the etch barrier layer is formed to a thickness of approximately 50 Å to approximately 150 Å.

11. The method of claim 1, wherein the gate patterns are formed in the cell region or the peripheral region.

12. The method of claim 1, wherein the plasma oxidation process is performed at a chamber temperature of approximately 300° C. to approximately 400° C.

13. The method of claim 1, wherein the plasma oxidation process is performed at a chamber temperature of approximately 300° C. to approximately 500° C.

14. The method of claim 1, wherein the capping layer is formed to a thickness of approximately 60 Å to approximately 100 Å.

15. The method of claim 1, wherein the etch barrier layer is formed to a thickness of approximately 70 Å to approximately 90 Å.
